(19) United States
(12) Patent Application Publication
(10) Pub. No.: US 2025/0159846 A1
(43) Pub. Date: May 15, 2025

(54) IMMERSION COOLING SYSTEM AND METHODS

(71) Applicant: Taiwan Semiconductor Manufacturing Co., Ltd., Hsinchu (TW)

(72) Inventors: Wei-Sheng LIN, Hsinchu (TW); Chung-Chiu WU, Hsinchu (TW)

(21) Appl. No.: 18/506,366

(22) Filed: Nov. 10, 2023

(51) Int. Cl. H05K 7/20

(52) U.S. Cl. CPC H05K 7/20818; H05K 7/203

(57) ABSTRACT

A method includes: forming a cooled device by cooling a device in and by a first container of an immersion cooler; performing semiconductor processing by a processing tool in data communication with the cooled device; determining whether the cooled device is in a condition to be removed from the immersion cooler; in response to the cooled device not being in the condition, cooling the device by the immersion cooler; and in response to the cooled device being in the condition, removing the device from the first container, including: positioning a second container over the first container; and with the second container in place covering the first container: opening a lid of the first container; and removing the device from the first container.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, data centers including large numbers of servers support planning and manufacturing of the ICs. Individual servers may be cooled by passive cooling, air cooling, water cooling or immersion cooling. None of these cooling methods has been entirely sufficient for various reasons.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagrammatic perspective view of a system for immersion cooling according to embodiments of the present disclosure.

FIGS. 2-6 are views of a system for immersion cooling according to various aspects of the present disclosure.

FIGS. 7 and 8 are flowcharts of methods according to various aspects of the present disclosure.

FIG. 9 is a diagram of a system for performing semiconductor processing in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

Semiconductor fabrication generally involves the formation of electronic circuits by performing multiple depositions, etchings, annealings, and/or implantations of material layers, whereby a stack structure including many semiconductor devices and interconnects between is formed. Prior to and continuous with the semiconductor fabrication, other support processes may be performed. For example, simulation and modeling, design and layout, supply chain management, quality control, energy management, research and development, security and data protection, inventory and logistics management and customer support are functions that provide support for semiconductor processing operations in a semiconductor foundry. Semiconductor processing itself, along with the support functions just mentioned, may leverage compute capabilities of a data center.

Briefly, elements of a data center can include physical infrastructure, servers and hardware, networking equipment, data storage systems, cooling systems, power infrastructure, security hardware/software and monitoring and management systems. The data center should have high availability and redundancy, as well as good scalability, which are beneficial to providing continuous support for the various semiconductor processing and support functionalities.

Immersion cooling is a cooling technique used in data centers and high-performance computing (HPC) environments where electronic components, such as servers or graphics processing units (GPUs), are submerged in a non-conductive liquid coolant rather than using air-based cooling methods. There are several benefits accrued by using immersion cooling. Some of these include improved cooling efficiency, higher power density, reduced energy consumption, silent operation, extended hardware lifespan, heat reuse opportunities, reduced data center footprint, safety and environmental benefits and easier hardware maintenance. However, immersion cooling also comes with its own set of challenges and considerations, such as initial setup costs, potential risks of leaks, and compatibility with existing hardware. For example, to cool servers in operation, the servers may be immersed in a tank that is filled with dielectric coolant. When the coolant heats up, the coolant may undergo a phase change from liquid to vapor to remove heat effectively. However, when the server is to be removed, e.g., for examination or replacement, a lid of the tank is opened to gain access to the server. During this process, the coolant vapor may escape to the open environment, which can present a safety and/or environmental pollution issue.

In embodiments of the disclosure, an enclosure is placed above the tank that fully covers the tank when the lid is open. The enclosure is beneficial to confine the coolant vapor in the enclosure without escaping to the outside environment. The enclosure can be mobile, so that it can be removed once a server removal, installation or swap operation is completed. This is also beneficial to sharing a single enclosure across a large number of tanks. A robot arm may be present in the enclosure to perform the selected function, e.g., removal of a malfunctioning server from the tank. The enclosure may also include a pump that can evacuate vapor and establish a negative pressure environment that is beneficial in allowing the lid to be opened. The enclosure may be integrated with or used with an automated materials handling system (AMHS), such as an overhead transport (OHT). The enclosure may include a filtration system that can filter vapor of the coolant in the enclosure. The enclosure may include a recycling system, such as a condenser, that can condense the vapor and store it for reuse in the tank.

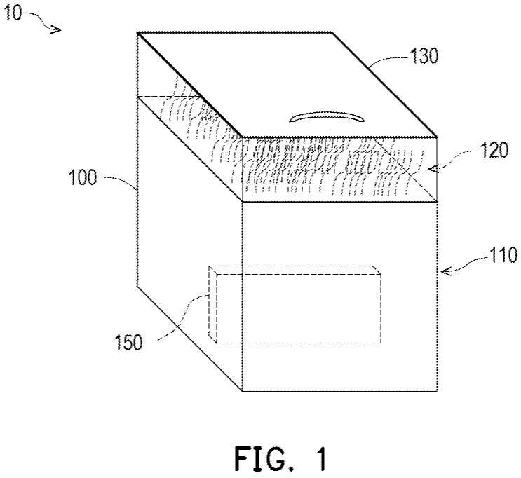

FIG. 1 is a diagrammatic perspective view of a cooling system 10 in accordance with various embodiments. The view of FIG. 1 is simplified, and one or more elements may be omitted from view for clarity of illustration.

The cooling system or “system” 10 includes a tank or “first container” 100 and a lid 130. The tank 100 may be filled partially with a liquid coolant or “coolant” 110. The coolant 110 may be a dielectric coolant. One or more server racks 150 (or high-performance computing, “HPC,” systems) may be positioned in the tank 100 and submerged in the coolant 110. An upper portion of the tank 100 may be substantially free of liquid coolant 110, but may have coolant vapor 120 and air present therein. The lid 130 covers the tank 100 and prevents the vapor 120 from escaping into the surrounding atmosphere or environment. In some embodiments, the cooling system 10 is an immersion cooling system. In some embodiments, the immersion cooling system is a one-phase, two-phase cooling system or multi-phase cooling system. When the coolant 110 heats up from heat of components of the server rack 150, the coolant 110 undergoes a phase change (e.g., from liquid state to vapor state) and effectively removes the heat. For example, the coolant 110 may have a boiling point that is in a range of about 50° C. to about 60° C. Vapor 120 rising through the coolant 110 agitates the coolant 110 to cool the surface of the server rack 150. The cooling system 10 may further include a condenser in the upper portion of the tank 100 that condenses the vapor 120 into liquid that falls back into the coolant 110. The condenser is not separately depicted in FIG. 1 for simplicity of illustration.

The server rack or HPC system 150 may include one or more of a motherboard, central processing unit (CPU), random access memory (RAM), storage drives, graphics processing unit (GPU), network interface cards, interconnects and cables. Some or all of the elements of the server rack 150 may be submerged in the coolant 110. In some embodiments, the server rack 150 may electrically connect to a passive device, an amplifier, a filter, a memory, combinations thereof or the like, which may be submerged in the coolant 110 or may be outside of the coolant 110. The passive device may include an inductor, capacitor or resistor.

When the server rack 150 is removed from the tank 100 for inspection, replacement or removal, the lid 130 of the tank is opened to provide access to the server rack 150. During this process, the coolant vapor 120 may escape into the open environment, which can be a safety or environmental issue. In embodiments of the disclosure, a second container or “enclosure” 200 is positioned over the tank 100, such that when the lid 130 is opened, the vapor 120 is contained within a enclosure 200 and does not escape into the surrounding environment.

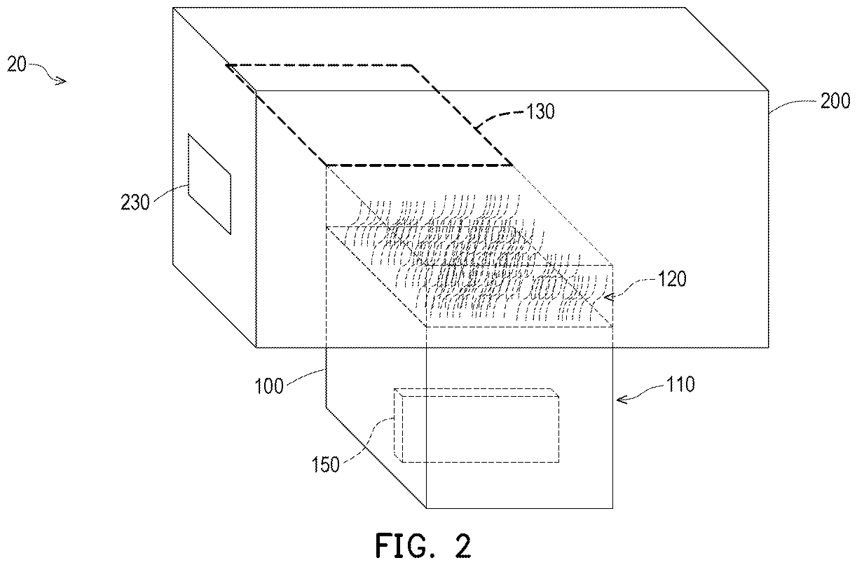

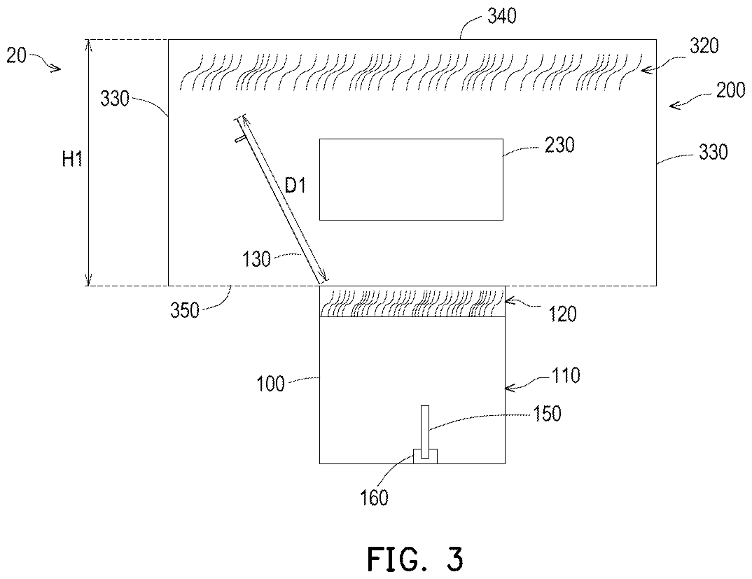

FIG. 2 is a diagrammatic perspective view of a system 20 including an enclosure 200 in accordance with various embodiments. FIG. 3 is a diagrammatic side view of the system 20.

The system 20 includes the tank 100, which is substantially the same as or similar in most respects to the tank 100 described above with reference to FIG. 1. In some embodiments, the enclosure 200 fully covers the tank 100 when the lid 130 is open. In some embodiments, the enclosure 200 substantially covers the tank 100 when the lid 130 is open. The enclosure 200 is beneficial to form a boundary that restricts diffusion of the vapor 120.

In FIG. 3, the enclosure 200 covers the tank 100. The enclosure 200 may have sidewalls 330 and a top wall 340. The enclosure 200 may include a bottom wall 350. In some embodiments, the bottom wall 350 has an opening or cutout through which the tank 100 and/or lid 130 may extend prior to opening the lid 130. The opening has profile that is larger than cross-sectional profile of the tank 100. In some embodiments, the bottom wall 350 is not present, which may be beneficial for simpler positioning of the enclosure 200 over the tank 100. Namely, the enclosure 200 may be a “semi-closed” enclosure 200. The bottom wall 350 being present, on the other hand, may be beneficial for improving containment of vapor 320 inside the enclosure 200. The sidewalls 330, top wall 340 and optional bottom wall 350 may be referred to collectively as “the walls.” The vapor 320 is the same as the vapor 120, except that the vapor 320 is in the enclosure 200 whereas the vapor 120 is inside the tank 100.

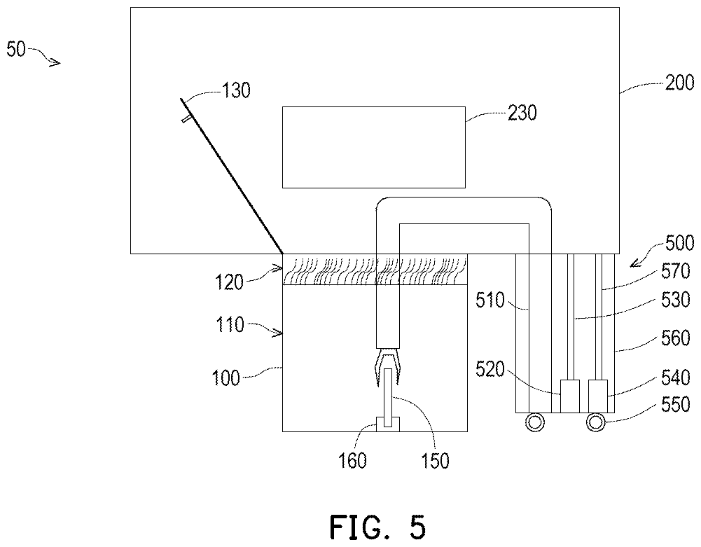

The walls 330, 340, 350 may be or include steel, such as stainless steel, powder-coated steel, or the like. In some embodiments, the walls 330, 340, 350 include aluminum, which may be beneficial to reducing weight of the enclosure 200. In some embodiments, the walls 330, 340, 350 include plastic, such as polypropylene or the like, which may be beneficial to reducing weight of the enclosure 200 even further. The sidewalls 330 may have height H1 that exceeds length D1 of the lid 130. Namely, the height H1 is large enough that the lid 130 has sufficient clearance to open to fully vertical within the enclosure 200. Generally, due to use of a robot arm 510 (see FIG. 5) to open the lid 130, the height H1 will exceed the length D1 by at least 1 centimeter to 20 centimeters, or more.

One or more of the walls 330, 340, 350 may include a window 230, which may be transparent. The window 230 may be or include tempered glass, safety glass, acrylic, plastic, or the like. Interior surfaces of the enclosure 200 may include one or more linings, such as polypropylene, or the like. The window 230 is beneficial for an operator or camera to observe operation of the tank 100 and/or the robot arm 510 (see FIG. 5) during removal, replacement or installation of a server rack 150.

In the system 20, the server rack 150 may be mounted to a frame or platform 160 within the tank 100. The frame or platform 160 is operable to hold the server rack 150 securely and position the server rack 150 at a selected depth within the cooling liquid that is beneficial for the server rack 150 to remain stable and properly submerged in the coolant 110, allowing for efficient heat transfer and cooling of the electronic components. The server rack(s) 150 are securely attached to the frame or platform 160 to prevent movement or shifting during the cooling process. In some embodiments, the system 20 has adjustable platforms or brackets to accommodate different server rack sizes or may have fixed mounting points for a selected server rack model. It is beneficial for the mounting system to provide proper support and stability so that the servers are fully immersed and that there are no gaps or air pockets between the servers and the cooling liquid. Proper immersion improves cooling efficiency and achieves benefits of immersion cooling, such as improved heat dissipation and reduced energy consumption.

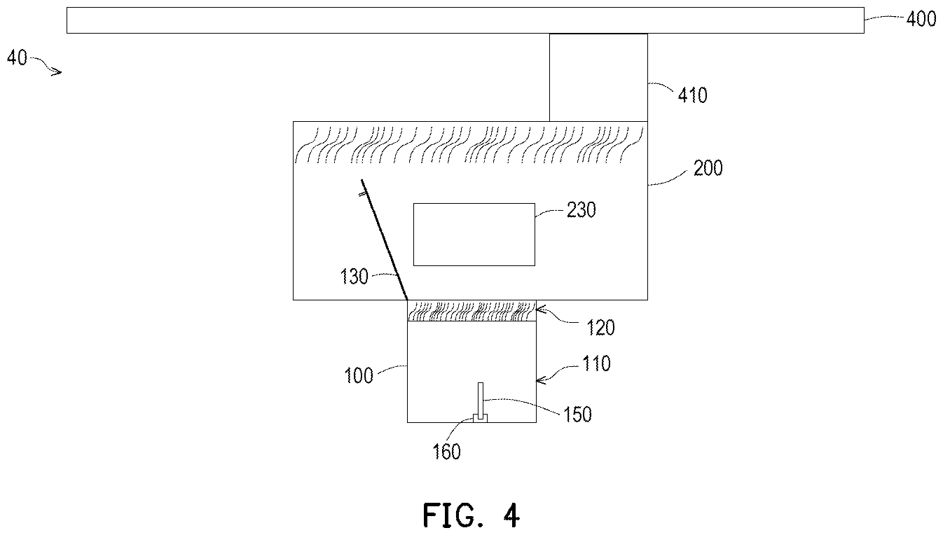

FIG. 4 depicts a system 40 in accordance with various embodiments. The system 40 includes the tank 100 and the enclosure 200 and further includes a track 400 and carrier 410 of an overhead transport (OHT) system.

The OHT system is a beneficial component of an automated materials handling system (AMHS) used in semiconductor manufacturing, logistics, and warehousing. The OHT system is designed to autonomously transport materials, products, or goods between different locations within a facility, often using an overhead track or rail system. The OHT system may include one or more vehicles (OHTs) 410. The OHT is an autonomous vehicle that travels along an overhead track 400. The OHT 410 may include wheels or rollers that engage with the track 400 to move smoothly. The OHTs 410 can be configured to transport various types of loads, including semiconductor wafer carriers, pallets, containers, or in the embodiments, the enclosure 200.

The overhead track 400 is a structure installed on the ceiling or overhead of a facility. The track 400 may include rails or guided pathways that guide the movement of the OHTs 410. The track layout can be selected to suit the facility's layout and material flow operations. The OHTs 410 may be equipped with guidance and control systems that are beneficial to precise navigation along the overhead track 400. Various technologies may be used for this purpose, such as laser-based positioning, magnetic sensors, or optical markers. The OHT 410 is equipped with a load handling mechanism selected to be beneficial to the material or product it transports (e.g., the enclosure 200). The load handling mechanism may include lifters, clamps, or vacuum-based systems to secure and move the enclosure 200 safely. The OHT 410 may be controlled by a central control system or an overarching software platform that manages movement and coordination of multiple OHTs. The control system optimizes material flow, coordinates traffic, and reduces wait times and collisions. At a loading station, materials or products, such as the enclosure 200, are placed onto the OHT. This can be done manually (e.g., by an operator) or automatically (e.g., by a robot arm). Once loaded, the OHT 410 moves along the overhead track following selected routes to deliver the enclosure 200 to the tank 100 or a nearby unloading station. At the unloading station, the OHT 410 may safely deposit the enclosure 200. The OHT system is beneficial for high levels of coordination and synchronization. Multiple OHTs may operate simultaneously, which improves efficient material flow and reduces idle time.

In some embodiments, the enclosure 200 may be delivered and/or positioned over the tank 100 by the OHT system. For example, the OHT or “carrier” 410 may be operable to transit along the track 400 and the enclosure 200 may be mounted to the carrier 410 to be mobile. This is beneficial to allow a single enclosure 200 to service more than one tank 100. In some embodiments, the enclosure 200 is attached to the track 400 by the carrier 410 during removal, installation or replacement of the server rack 150. In some embodiments, the carrier 410 delivers the enclosure 200 to the tank 100, but then transfers the enclosure 200 to another mount or vehicle that is on a floor instead of overhead (e.g., attached to a ceiling). Keeping the enclosure 200 attached to the OHT 410 during the removal, installation or replacement operation may be beneficial to simplify positioning of the enclosure 200 over the tank 100, as the enclosure 200 may be let down over the tank 100 instead of being extended over the tank 100 to clear the lid 130 and any element (e.g., a handle) protruding upward therefrom. Once the removal, installation or replacement operation is completed, the carrier 410 may remove the enclosure 200 from over the tank 100 and transit the enclosure 200 to another tank or to a storage. For example, the carrier 410 may lift or retract the enclosure 200 to clear the tank 100, then shift the enclosure 200 along the rail 400 to another tank or to an unloading station.

FIG. 5 is a diagram of a system 50 in accordance with various embodiments. In FIG. 5, the enclosure 200 is transported to the tank 100 by a vehicle 500. The vehicle 500 may include one or more of a robot arm 510, a pump 520 and a filter 540. The vehicle 500 may have a housing 560 mounted on wheels 550. The vehicle 500 is mobile to transport the enclosure 200 near to the tank 100 and hold the enclosure 200 in position over the tank 100 during the removal, installation or replacement operation. The pump 520, filter 540 and robot arm 510 may be mounted in the housing 560.

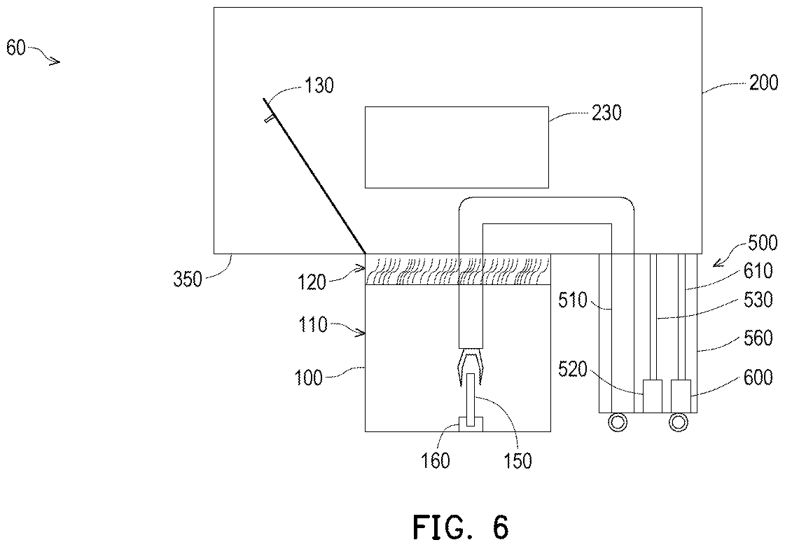

The vehicle 500 may have payload capacity that includes the enclosure 200, the robot arm 510 and optionally the pump 520, the filter 540 and/or a recycling system 600 (depicted in FIG. 6). Dimensions of the vehicle 500 are selected to be beneficial for the vehicle 500 to navigate through narrow aisles and confined spaces within a semiconductor fab. The length, width, and height may be beneficial for efficient movement and to accommodate the enclosure 200. The vehicle 500 may be capable of moving at a controlled and consistent speed while transporting the enclosure 200. Acceleration and deceleration rates are selected to prevent damage to the enclosure 200 and surrounding equipment and/or injury to operators. The vehicle 500 may include a navigation and control system that is beneficial for accurate positioning and collision avoidance within the fab environment. The navigation and control system may include laser or vision-based guidance systems, sensors, and automated control algorithms. The vehicle 500 may adhere to cleanroom standards, such that the vehicle 500 does not generate particles or contaminants that impact wafer cleanliness. To that end, the vehicle 500 be equipped with selected filters and materials to maintain a clean environment. The vehicle 500 may equipped with a reliable and gentle load handling system to securely grip and transport the enclosure 200 without causing any damage to the enclosure 200 or the tank 100. The vehicle 500 may be capable of seamless communication and integration with a central control system or manufacturing execution system (MES) of the fab, which is beneficial for efficient job scheduling, tracking, and coordination with other equipment and processes. The vehicle 500 may include safety features that are beneficial to protect personnel and prevent accidents, and may include emergency stop buttons, obstacle detection, and fail-safe mechanisms. The vehicle 500 may be powered by one or more batteries. For battery-powered vehicles 500, the battery life may be selected to meet operational parameters of the fab. Efficient charging stations may be positioned in the fab to reduce downtime due to battery charging. In some embodiments, the vehicle 500 does not include a motor, but is instead moved by a human operator.

The robot arm 510 may be operable to grasp the server rack 150, remove the server rack 150 from the tank 100, and place the server rack 150 in the housing 560. During an installation operation, the robot arm 510 may be operable to grasp a server rack in the housing 560, transport the server rack into the tank 100 and mount the server rack in a frame or platform in the tank 100.

The robot arm 510 may be a multi-jointed mechanical arm that is designed to mimic human arm movements, with three to six degrees of freedom, allowing the robot arm 510 to move in multiple directions and rotate around different axes. The robot arm 510 may be mounted on a fixed base or installed on a mobile platform, such as the vehicle 500 or the OHT 410. The robot arm 510 may include an end effector, or gripper, selected to securely hold and transport server racks 150 without causing damage or contamination. In some embodiments, different types of grippers may be used, such as vacuum-based grippers, edge-grip grippers, or vacuum and edge-grip combinations. Generally, because the robot arm 510 is operated in a submerged environment, the robot arm 510 includes edge-grip grippers. The robot arm 510 may be controlled by a sophisticated system that is beneficial to operate with high precision and accuracy, coordinating movements thereof with other equipment in the removal, installation or replacement process. The robot arm 510 may include vision systems and sensors that are beneficial to map position and orientation of the server rack 150, enabling the robot arm 510 to pick up and place the server rack 150 at precise locations, e.g., in the housing 560. In some embodiments, the robot arm 510 includes one or more of a distance sensor, gyroscope sensor, acceleration sensor, lenses and/or cameras, and the like. The robot arm 510 may include safety features, such as collision detection and emergency stops that are beneficial to a safe working environment. The robot arm 510 may be integrated into a central control system or MES of the semiconductor fab or data center, communicating with other equipment and maintaining a cleanroom-compatible environment. In the above description, the robot arm 510 is operable to remove, replace or install a server rack 150 in the tank 100. In some embodiments, the robot arm 510 may remove, replace or install other parts in the tank 100, such as the frame 160, cables, or other parts.

The robot arm 510 is generally operable to extend into the tank 100 and is mounted in the vehicle 500 or the OHT 410. As such, the bottom wall 350 of the enclosure 200 may include one or more second openings that are positioned over the vehicle 500. The second opening(s) may include a single opening that is substantially the same size as the horizontal cross-sectional profile of the vehicle 500, such that the inside of the housing 560 and the enclosure 200 are a single connected space. In some embodiments, the bottom wall 350 may cover the vehicle 500, and may include the second openings that correspond to size of the robot arm 510 and/or the tube 530 connected to the pump 520. Namely, the pump 520 may lower pressure inside the enclosure 200 without substantially lowering pressure within the housing 560 of the vehicle 500.

The pump 520 is mounted in the vehicle 500 and may be in communication with the enclosure 200 via a pipe or line 530 that extends from the pump 520 to the enclosure 200. The pump 520 may be a mobile vacuum pump that is beneficial for creating and maintaining a vacuum or near-vacuum environment in the enclosure 200. One advantage of a mobile vacuum pump is portability, allowing the pump 520 to be easily moved and deployed at different locations within a facility or even between different sites. The pump 520 may include wheels and has a compact design, making it easy to transport and position in different work areas. In some embodiments, the pump 520 includes a motor-driven system that draws air and/or gases (e.g., the vapor 120) from the enclosure 200, effectively lowering pressure to a selected vacuum level. In some embodiments, the pump 520 is a rotary vane pump, diaphragm pump, scroll pump, or the like. Flow rate and vacuum capabilities of the pump 520 may be selected to be beneficial for the environment of the enclosure 200. The pump 520 may be equipped with safety features and monitoring systems to control and/or monitor vacuum conditions, preventing contamination or adverse effects on the process. Creating a vacuum, near-vacuum or reduced pressure environment in the enclosure 200 may be beneficial to reduce force applied to open the lid 130. FIG. 5 depicts a single pump 520. In some embodiments, two or more pumps 520 are positioned in the housing 560 and are in communication with the enclosure 200 for reducing pressure in the enclosure 200.

The filter 540 may be connected to the enclosure 200 by a pipe or tube 570. The filter 540 may be a vapor-phase filter that is beneficial to capture and remove volatile organic compounds (VOCs), gases, and other impurities present in the vapor 120 of the coolant 110. These impurities can arise from outgassing of materials within the cooling system 20 or from the electronic components themselves. The filter 540 may contain adsorbent materials, such as activated carbon or other selected media, which have a high surface area and are capable of adsorbing gases and VOCs. As the coolant vapor 120 passes through the filter 540, the adsorbent materials trap and retain the impurities, allowing only clean vapor 120 to continue its circulation in the cooling system 20. The vapor-phase filter is generally located within the vehicle 500 but may also be integrated into the enclosure 200 in some embodiments. The filter 540 may be replaced periodically to maintain efficiency. In some embodiments, the filter 540 is integrated with the pump 520 instead of being a separate element installed in the vehicle 500. In such embodiments, the tube 570 may be omitted.

The robot arm 510, the pump 520 and the filter 540 may each be powered electrically. In some embodiments, the vehicle 500 includes an internal power supply, such as a battery that provides power to the robot arm 510, the pump 520 and the filter 540. In some embodiments, the vehicle 500 includes an electrical cord that allows the robot arm 510, the pump 520 and the filter 540 to be powered by a main electrical grid, for example, by plugging in to a power outlet in the fab.

In FIG. 6, a system 60 is depicted in accordance with various embodiments. In some embodiments, the vehicle 500 has a recycling system 600 therein. The recycling system 600 may include one or more of a condenser for condensing the vapor 120 inside the housing 560 and for storing liquid coolant formed from the vapor 120 by the condenser. The condenser is a beneficial component responsible for efficient removal of heat from the vapor 120. As the coolant 110 circulates through the tank 100 and comes into contact with the hot electronic components of the server rack 150, the coolant 110 absorbs heat and evaporates into the vapor 120. The condenser is operable to cool and condense the vapor 120 back into a liquid state (e.g., the coolant 110), allowing the coolant 110 to recirculate and continue the cooling process. The condenser may be located inside the housing 560 and may be equipped with a cooling medium, such as water or air. The vaporized coolant 120 flows through or over the condenser coils, where the vapor 120 loses heat to the cooling medium, causing the vapor 120 to condense back into liquid form (e.g., the coolant 110). The coolant 110 is then returned to the tank 100 to cool the server rack 150 once again, completing the cooling cycle.

In some embodiments, the recycling system 600 includes a storage that stores the coolant 110 formed from the vapor 120 by the condenser. The storage may be made from a material that is chemically compatible with the coolant 110. The coolant 110 is generally a dielectric fluid, such as mineral oil-based or synthetic fluid. Materials like stainless steel, polypropylene, or high-density polyethylene (HDPE) may be suitable for storing these types of coolants 110. The storage may be a vat or container that is in fluid communication with the condenser. In some embodiments, the recycling system 600 is integrated with or connected directly to the pump 520. In some embodiments, the recycling system 600 is a standalone system that is not connected to the pump 520 but operates independently therefrom. When connected to the pump 520, the air including vapor 120 evacuated from the enclosure 200 may be transported into the condenser and converted into liquid coolant 110 that is stored in the storage.

Although the systems 50 and 60 are depicted including different elements, it should be understood that the systems 50 and 60 may include one or more elements of the other system. For example, the system 60 may include the filter 540 and the recycling system 600. Namely, the vehicle 500 may have the robot arm 510 and one or more of the pump 520, the filter 540 and the recycling system 600 positioned in the housing 560 thereof.

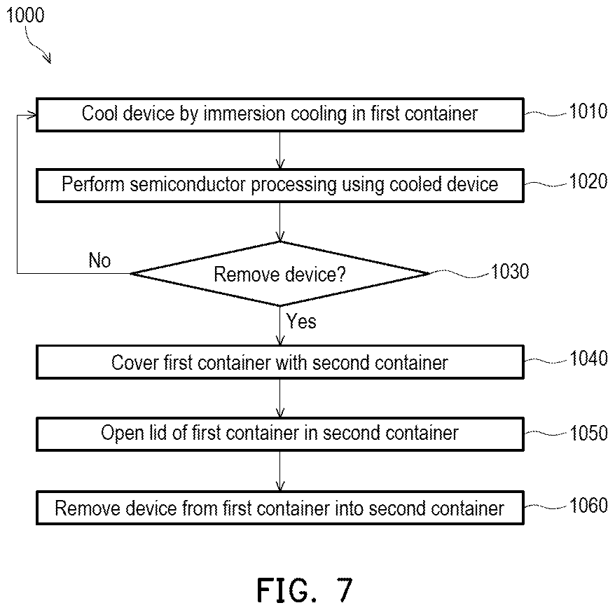

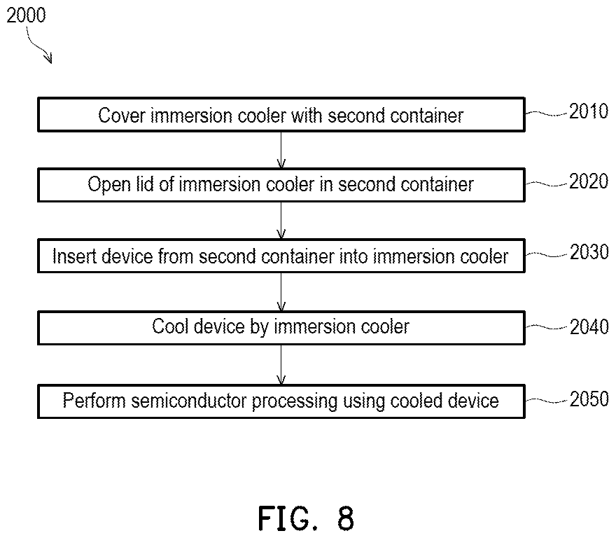

FIGS. 7 and 8 are flowcharts illustrating methods 1000, 2000 of processing a semiconductor device according to various aspects of the present disclosure. The acts illustrated in FIGS. 7 and 8 may be performed in accordance with the systems 20, 40, 50, 60 or a system 90 described with reference to FIGS. 2-6 and 9. FIGS. 7 and 8 illustrate flowcharts of methods 1000, 2000 for processing a semiconductor device, according to one or more aspects of the present disclosure. Methods 1000, 2000 are examples and are not intended to limit the present disclosure to what is explicitly illustrated in methods 1000, 2000. Additional acts can be provided before, during and after the methods 1000, 2000 and some acts described can be replaced, eliminated, or moved around for additional embodiments of the methods. For example, the methods 1000, 2000 may also be used for removing, replacing or installing server racks in a data center that does not engage in semiconductor processing by omitting acts 1020 and 2050 from the methods 1000, 2000, respectively. Not all acts are described herein in detail for reasons of simplicity. For example, acts related to detailed fabrication operations of IC dies on a wafer are omitted from view and not described in detail herein. Similarly, acts that follow the acts of methods 1000, 2000, for example, that are related to singulation and packaging of IC dies are also omitted from view and not described in detail herein. Acts of methods 1000, 2000 are described below with reference to elements of the systems 20, 40, 50, 60 and 90 of FIGS. 2-6 and 9. It should be understood that the methods 1000, 2000 are not limited to being performed by the systems 20, 40, 50, 60 and 90, and may be performed by systems that differ in one or more respects from the systems 20, 40, 50, 60 and 90 in other embodiments.

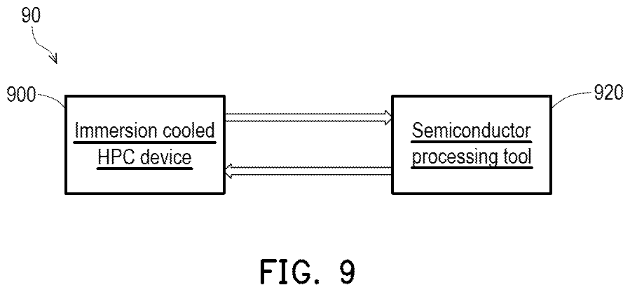

FIG. 9 depicts a system 90 for performing semiconductor processing in accordance with various embodiments. In the system 90, an immersion cooled HPC device 900 is in data communication with a semiconductor processing tool 920. The HPC device 900 may be the server rack 150, in some embodiments, and may control and/or provide data to the semiconductor processing tool 920. The HPC device 900 may receive output data, e.g., metrology data, from the semiconductor processing tool 920.

The semiconductor processing tool 920 may be or include an etch tool, deposition tool, lithography tool, metrology tool, chemical mechanical planarization (CMP) tool, rapid thermal processing (RTP) tool, ion implantation tool, chemical vapor deposition (CVD) tool, physical vapor deposition (PVD), atomic layer deposition (ALD) tool, annealing tool, wet processing tool, plasma ashing tool, wafer bonding tool, inspection tool, defect review tool, chemical delivery system (CDS) tool, gas delivery system (GDS) tool, wafer probing tool, automated test equipment (ATE) tool, advanced packaging equipment tool or the like.

In some embodiments, the HPC device or server rack 900 is in data communication with one or more of the above semiconductor processing tools 920 via a data network. For example, the immersion-cooled server rack 900 may be connected to a data center network, which includes switches, routers, and other networking equipment. The data center network allows the server rack to communicate with other servers, storage systems, and external resources. The server rack may communicate with the semiconductor processing tools indirectly through the data center network. Data transfer between the server rack and the processing tools occurs over the network infrastructure. In a semiconductor fab, the processing tools may be part of an automated production line, and their operations are managed by central control systems or manufacturing execution systems (MES). The control systems send commands and instructions to the processing tools 920 based on the data received from various sources, including the immersion-cooled server rack 900. The immersion-cooled server rack 900 may process data and perform various computational tasks beneficial to the semiconductor manufacturing process. The server rack 900 may generate data related to simulations, data analysis, or other processing steps beneficial for semiconductor fabrication. The communication between the immersion-cooled server rack 900 and the processing tools 920 may follow standard data exchange protocols, such as TCP/IP (Transmission Control Protocol/Internet Protocol). The immersion-cooled server rack 900 may also be connected to storage systems or databases that store and retrieve data relevant to the semiconductor manufacturing process.

In FIG. 7, the method 1000 begins with act 1010, which is cooling a device by immersion cooling in a first container. The device may be the server rack or HPC device 150. The device 150 is submerged in coolant 110 in the tank 100. The first container may be the tank 100. The device 150 may be cooled in the tank 100 as described with reference to FIGS. 1 and 2. For example, the device 150 may be cooled by coolant 110 having a boiling point in a range of about 50 degrees Celsius to about 60 degrees Celsius. Vapor 120 may be generated by heat of electronic components of the server rack 150. The vapor 120 bubbles up and agitates the coolant 110, further distributing the coolant 110 over surfaces of the server rack 150.

Act 1020 follows act 1010. While the device is cooled, semiconductor processing is performed in act 1020 using the cooled device. As described above, the server rack 150, 900 may provide data, instructions, recipes or other information to the semiconductor processing tools 920 that are used by the semiconductor processing tools 920 when processing a wafer to form IC devices.

The wafer may be or include a semiconductor device. The semiconductor device may be any semiconductor device, such as, but not limited to, a logic device, a memory device or any other semiconductor device. The semiconductor device generally includes a semiconductor device layer, a frontside interconnection structure, an optional backside interconnection structure and one or more electrical contacts. In most embodiments, the wafer is a semiconductor wafer that has multiple integrated circuit (IC) chips or dies formed therein. The semiconductor device layer may include a semiconductor substrate, which may be referred to as the substrate. The substrate may be any suitable substrate. In some embodiments, the substrate may be a semiconductor wafer. In some embodiments, the substrate may be a monocrystalline silicon (Si) wafer, an amorphous Si wafer, a gallium arsenide (GaAs) wafer, or any other semiconductor wafer.

The semiconductor device layer includes one or more semiconductor devices. The semiconductor devices included within the semiconductor device layer may be any semiconductor devices in various embodiments. In some embodiments, the semiconductor device layer includes one or more transistors, which may include any suitable transistor structures, including, for example, planar transistors, fin-type transistors (FinFETs), or nanostructure transistors, such as gate-all-around (GAA) transistors, or the like. In some embodiments, the semiconductor device layer includes one or more GAA transistors. In some embodiments, the semiconductor device layer may be a logic layer that includes one or more semiconductor devices, and may further include their interconnection structures, that are configured and arranged to provide a logical function, such as AND, OR, XOR, XNOR, or NOT, or a storage function, such as a flipflop or a latch. In some embodiments, the semiconductor device layer may include a memory device, which may be any suitable memory device, such as, for example, a static random access memory (SRAM) device. The memory device may include a plurality of memory cells that are constructed in rows and columns, although other embodiments are not limited to this arrangement. Each memory cell may include multiple transistors (e.g., six) connected between a first voltage source (e.g., VDD) and a second voltage source (e.g., VSS or ground) such that one of two storage nodes can be occupied by the information to be stored, with the complementary information stored at the other storage node. The semiconductor device layer of the device may further include various circuitry that is electrically coupled to the semiconductor device layer. For example, the semiconductor device layer may include power management or other circuitry that is electrically coupled to the one or more semiconductor devices of the semiconductor device layer. The power management circuitry may include any suitable circuitry for controlling or otherwise managing communication signals, such as input power signals, to or from the semiconductor devices of the semiconductor device layer. In some embodiments, the power management circuitry may include power-gating circuitry which may reduce power consumption, for example, by shutting off the current to blocks of the circuit (e.g., blocks or electrical features in the semiconductor device layer) that are not in use, thereby reducing stand-by or leakage power. In some embodiments, the semiconductor device layer includes one or more switching devices, such as a plurality of transistors, that are used to transmit or receive electrical signals to and from the semiconductor devices in the semiconductor device layer, such as to turn on and turn off the circuitry (e.g., transistors, etc.) of the semiconductor device layer.

The semiconductor processing may include any processing that may be performed by the semiconductor processing tools 920 described with reference to FIG. 9. For example, the semiconductor processing may include photolithography, etching, deposition (e.g., CVD, PVD, ALD), rapid thermal annealing, plasma ashing, or the like. One or more parameters, scheduling or instructions associated with the semiconductor processing may be supplied by the server rack 150, 900 to the semiconductor processing tool 920.

Act 1030 follows act 1020. During or following a semiconductor processing operation in act 1020, a determination is made whether the device (e.g., the server rack 150) is in a condition to be removed in act 1030. For example, the server rack 150, 900 may be selected for removal due to a malfunction, routine maintenance, or another suitable reason. In response to the server rack 150 not being slated for removal, the method 1000 returns to act 1010, wherein the server rack 150 continues to be cooled, and semiconductor processing proceeds in act 1020 leveraging the server rack 150. In response to the server rack 150 being selected for removal, the method 1000 proceeds to act 1040. In some embodiments, the device is to be swapped from one frame to another frame in the same tank. For example, the server rack 150 may be disconnected from the frame 160 and installed in another different frame within the tank 100. In such an embodiment, the server rack 150 may be submerged entirely or partially continuously throughout the swapping operation. The swapping may be performed by the robot arm 510.

Act 1040 follows act 1030 when the server rack or HPC device 150, 900 is to be removed from the tank 100. In act 1040, the tank 100 is covered by a second container (e.g., the enclosure 200), which is beneficial to contain vapor 120 that evaporates from the coolant 110. The tank 100 may be covered by the enclosure 200 by any of the methods described with reference to FIGS. 2-6. For example, the enclosure 200 may be lowered to a position over the tank 100 by the OHT 410. In another example, the enclosure 200 may be positioned over the tank 100 by the vehicle 500. In some embodiments, the enclosure 200 includes the bottom wall 350 that has an opening corresponding to the tank 100. The enclosure 200 may be lowered over the tank 100 under guidance of an optical guidance system. For example, the enclosure 200 may have one or more cameras attached thereto that capture images of the tank 100 or identification markers, such as visible patterns or the like. The enclosure 200 may be lowered to a position at which the bottom wall 350 is substantially coplanar with the lid 130 of the tank 100. In some embodiments, the enclosure 200 is lowered to a position that is somewhat below that of an upper surface of the tank 100.

Act 1050 follows act 1040. In act 1050, following covering the first container with the second container, a lid of the first container is opened. For example, following positioning the enclosure 200 over the tank 100, the lid 130 of the tank 100 is opened. This is beneficial to contain any vapor 120 that may escape the tank 100 in the enclosure 200 that is over the tank 100. In some embodiments, the lid 130 may be opened prior to positioning the enclosure 200 over the tank 100, but some vapor 120 may escape into the surrounding environment. However, some benefit is still obtained due to the enclosure 200 being over the open tank 100 for most of the time spent performing the removal, replacement or installation operation by the robot arm 510.

Act 1060 follows act 1050. Following opening the lid in act 1050, the device is removed from the first container. For example, the server rack or HPC device 150 that is submerged in the coolant 110 in the tank 100 is gripped by the robot arm 510, then the robot arm 510 transfers the server rack 150 to the housing 560.

Additional acts may follow act 1060. For example, after the server rack 150 is placed in the housing 560 of the vehicle 500 or in the OHT 410 by the robot arm 510, the vehicle 500 or the OHT 410 may lift the enclosure 200 from over the tank 100 and transport the enclosure 200 away from the tank 100, for example, to another tank that has a server rack or HPC device to be removed, replaced or installed, or to an unloading area where the enclosure 200 may be stored for subsequent use.

In some embodiments, after the server rack or HCP device 150 is removed from the tank 100, the robot arm 510 may install a replacement server rack or HCP device in the tank 100. For 7example, the robot arm 510 may grip the replacement server rack that is stored in the housing 560, then lower the replacement server rack into the coolant 110 in the tank 100 and install the replacement server rack into the frame 160.

FIG. 8 is a flowchart of method 2000 in accordance with various embodiments.

In FIG. 8, the method 2000 begins with act 2010, which includes covering an immersion cooler with a second container. For example, the tank 100 may be covered by the enclosure 200, similar to as described with respect to FIGS. 2-6 and act 1040 of FIG. 7.

Act 2020 follows act 2010. In act 2020, following covering the immersion cooler with the second container, the lid of the immersion cooler is opened. Act 2020 is the same as or similar in most respects to act 1050 of method 1000 of FIG. 7. Namely, the lid 130 of the tank 100 may be opened with the enclosure 200 in place thereover. Or, in some embodiments, the lid 130 may be opened just prior to act 2010 in which the enclosure 200 is positioned over the tank 100.

Act 2030 follows act 2020. In act 2030, following opening the lid of the immersion cooler, a device may be installed in the immersion cooler from the second container. For example, a server rack or HPC device may be stored in the housing 560 of the vehicle 500 or in the OHT 410. The server rack or HPC device may be gripped by the robot arm 510, then transferred by the robot arm 510 into the coolant 110 in the tank 100. The robot arm 510 may install the server rack or HPC device into the frame 160 to be submerged in the coolant 110 in the tank 100. Then, the robot arm 510 may retract back into the vehicle 500 or OHT 410.

Act 2040 follows act 2030. In act 2040, following installing the device in the immersion cooler, the device is cooled by the immersion cooler, which may be similar in most respects to act 1010 of method 1000 of FIG. 7. For example, a server rack or HPC device may be cooled by the coolant 110 that is a dielectric coolant in the tank 100. The coolant 110 may vaporize due to high temperatures of electronic chips of the server rack or HPC device, which agitates the coolant 110 to flow over surfaces of the server rack or HPC device, thereby cooling the server rack or HPC device.

Act 2050 follows act 2040. In act 2050, following or during the device being cooled by the immersion cooler, the device is used in association with semiconductor processing. Act 2050 may be similar in most respects to act 1020. The semiconductor processing may be any of the operations described with respect to act 1020 of FIG. 7. For example, the HPC device cooled by the immersion cooler may provide support (e.g., scheduling, recipe, control) to a tool (e.g., photolithography tool, deposition tool, etch tool) of a semiconductor fab.

It should be understood that, in some embodiments, act 2050 may be omitted or modified. For example, act 2050 may be modified to perform computing that is unrelated to semiconductor processing, such as computing associated with cloud computing services or any task that can be supported by compute of the HPC device.

Embodiments may provide advantages. The enclosure 200 that is over the tank 100 while the lid 130 is open contains vapor 120 that would escape into the surrounding environment otherwise. Containing the vapor 120 improves environmental cleanliness and safety. The enclosure 200 may be carried by the vehicle 500 or the OHT 410, so as to be mobile, such that the single enclosure 200 may be used to service multiple immersion cooling tanks.

In accordance with at least one embodiment, a method includes: forming a cooled device by cooling a device in and by a first container of an immersion cooler; performing semiconductor processing by a processing tool in data communication with the cooled device; determining whether the cooled device is in a condition to be removed from the immersion cooler; in response to the cooled device not being in the condition, cooling the device by the immersion cooler; and in response to the cooled device being in the condition, removing the device from the first container, including: positioning a second container over the first container; and with the second container in place covering the first container: opening a lid of the first container; and removing the device from the first container.

In accordance with at least one embodiment, a method includes: covering an immersion cooler by a container; with the container in place over the immersion cooler: opening a lid of the immersion cooler; and inserting a device into the immersion cooler; cooling the device by the immersion cooler; and performing semiconductor processing by a processing tool in data communication with the device cooled by the immersion cooler.

In accordance with at least one embodiment, a system includes: an immersion cooler having a tank and a lid that covers the tank; a device in the tank of the immersion cooler; an enclosure; and a vehicle having a housing, wherein the vehicle, in operation: positions the enclosure over the tank; and with the enclosure in position over the tank, removes the device from the tank and places the device in the housing.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a cooled device by cooling a device in and by a first container of an immersion cooler;
performing semiconductor processing by a processing tool in data communication with the cooled device;
determining whether the cooled device is in a condition to be removed from the immersion cooler;
in response to the cooled device not being in the condition, cooling the device by the immersion cooler; and
in response to the cooled device being in the condition, removing the device from the first container, including:
positioning a second container over the first container; and
with the second container in place covering the first container:
opening a lid of the first container; and
removing the device from the first container.

2. The method of claim 1, wherein the removing the device includes removing the device by a robot arm.

3. The method of claim 2, wherein the removing the device by a robot arm includes removing the device by the robot arm that is mounted in a vehicle.

4. The method of claim 3, wherein the removing the device includes removing the device by the robot arm that is mounted in an overhead transport.

5. The method of claim 3, further comprising:
lowering pressure in the second container via a pump in the vehicle.

6. The method of claim 3, further comprising:
filtering vapor of coolant of the first container by a filtration system in the vehicle.

7. The method of claim 3, further comprising:
condensing vapor of coolant of the first container into liquid coolant by a recycling system in the vehicle.

8. The method of claim 7, further comprising:
storing the liquid coolant in a storage of the recycling system in the vehicle.

9. A method comprising:
covering an immersion cooler by a container;
with the container in place over the immersion cooler:
opening a lid of the immersion cooler; and
inserting a device into the immersion cooler;
cooling the device by the immersion cooler; and
performing semiconductor processing by a processing tool in data communication with the device cooled by the immersion cooler.

10. The method of claim 9, further comprising:
prior to the covering an immersion cooler, transporting the container by a vehicle, the container being mounted to the vehicle, the vehicle holding the container over the immersion cooler.

11. The method of claim 10, wherein the covering an immersion cooler includes lowering the container to a position over the immersion cooler by an overhead transport.

12. The method of claim 11, further comprising:
after the inserting a device, lifting the container and transporting the container away from the immersion cooler by the overhead transport.

13. The method of claim 10, wherein the transporting the container by a vehicle includes transporting the container by the vehicle having a robot arm and a pump positioned therein.

14. The method of claim 13, wherein the transporting the container by a vehicle includes transporting the container by the vehicle further having a filtration system and a recycling system therein.

15. A system, comprising:
an immersion cooler having a tank and a lid that covers the tank;
a device in the tank of the immersion cooler;
an enclosure; and
a vehicle having a housing, wherein the vehicle, in operation:
positions the enclosure over the tank; and
with the enclosure in position over the tank, removes the device from the tank and places the device in the housing.

16. The system of claim 15, further comprising:
a robot arm in the vehicle, the robot arm, in operation, gripping the device in the tank and transferring the device to the housing.

17. The system of claim 16, wherein the vehicle is an overhead transport.

18. The system of claim 16, further comprising:
a pump in the vehicle, wherein the pump, in operation, lowers pressure in the enclosure and the tank during removal of the device from the tank.

19. The system of claim 18, further comprising:
a filter in the vehicle, wherein the filter, in operation, filters vapor of coolant of the tank.

20. The system of claim 19, further comprising:
a condenser in the vehicle, wherein the condenser, in operation, forms liquid coolant from the vapor.
